(19) United States
(12) Patent Application Publication
(10) Pub. No.: US 2022/0149186 A1
(43) Pub. Date: May 12, 2022

(54) RUGGED LDMOS WITH DRAIN-TIED FIELD PLATE

(71) Applicant: Texas Instruments Incorporated, Dallas, TX (US)

(72) Inventors: Henry Litzmann Edwards, Garland, TX (US); Gang Xue, San Jose, CA (US)

(73) Assignee: Texas Instruments Incorporated, Dallas, TX (US)

(21) Appl. No.: 17/092,485

(22) Filed: Nov. 9, 2020

(51) Int. Cl. H01L 29/66; H01L 29/78; H01L 29/40; H01L 29/08; H01L 21/762

(52) U.S. Cl. CPC H01L 29/66689; H01L 29/7816; H01L 21/76202; H01L 29/0873; H01L 29/402

(57) ABSTRACT

A semiconductor device including a substrate having a semiconductor layer containing a laterally diffused metal oxide semiconductor (LDMOS) transistor, including a body region of a first conductivity type and a drift region of an opposite conductivity type. A gate dielectric layer over a channel region of the body, the gate dielectric extending over a junction between a body region and the drift region with a gate electrode on the gate dielectric and a drain contact in the drain drift region, having the second conductivity type. A field relief dielectric layer on the drain drift region extending from the drain region to the gate dielectric, having a thickness greater than the gate dielectric layer. A drain-tied field plate on the field relief dielectric, the drain-tied field plate extending from the drain region toward the gate with an electrical connection between the drain-tied field plate and the drain region.

### CROSS-REFERENCE TO RELATED APPLICATIONS

This application is related to U.S. Provisional patent application Ser. No. ______ (Texas Instruments Docket No. TI-92752US01), filed on even date herewith and hereby incorporated herein by reference in its entirety.

### FIELD

This disclosure relates to the field of microelectronic devices. More particularly, but not exclusively, this disclosure relates to laterally diffused metal oxide semiconductor (LDMOS) devices.

### BACKGROUND

The invention relates (LDMOS) transistors, and in particular to an LDMOS transistor with improved ruggedness. As power semiconductor devices such as DC-DC-converters are scaled to the next generation of devices, there is a desire to improve performance, decrease die size, and increase the safe operating area (SOA) of the semiconductor device. Increasing the SOA of the semiconductor device is a method to improve the overall ruggedness of the device.

### SUMMARY

This summary is provided to introduce a brief selection of disclosed concepts in a simplified form that are further described below in the detailed description including the drawings provided. This summary is not intended to limit the claimed subject matter's scope.

Disclosed examples include semiconductor devices including drain extended metal oxide semiconductor (MOS) transistors, referred to herein as DEMOS transistors, that include drain-tied field plates adjacent to the drain ohmic contact regions. Disclosed examples provide an associated process flow for forming such DEMOS transistors.

### BRIEF DESCRIPTION OF THE VIEWS OF THE DRAWINGS

FIG. 1A through FIG. 1L show cross sections of a semiconductor device, depicted in various stages of formation.

FIG. 2 depicts a top down figure of a semiconductor device where the gate electrode and drain tied polycrystalline silicon layer are in a “racetrack” or closed-loop configuration, according to one example.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), for example. As another example, silicon nitride may be a silicon-rich silicon nitride or an oxygen-rich silicon nitride. Silicon nitride may contain some oxygen, but not so much that the materials dielectric constant is substantially different from that of high purity stoichiometric silicon nitride.

It is noted that terms such as top, bottom, and under may be used in this disclosure. These terms should not be construed as limiting the position or orientation of a structure or element, but should be used to provide spatial relationship between structures or elements.

Drain extended transistors can include drain-extended NMOS (DENMOS), drain-extended PMOS (DEPMOS), and/or laterally diffused MOS (LDMOS) transistors, as well as groups of DENMOS and DEPMOS, referred to as complimentary drain extended MOS or DECMOS transistors. Described examples include doped regions of various semiconductor structures which may be characterized as p-doped and/or n-doped regions or portions, and include regions that have majority carrier dopants of a particular type, such as n-type dopants or p-type dopants.

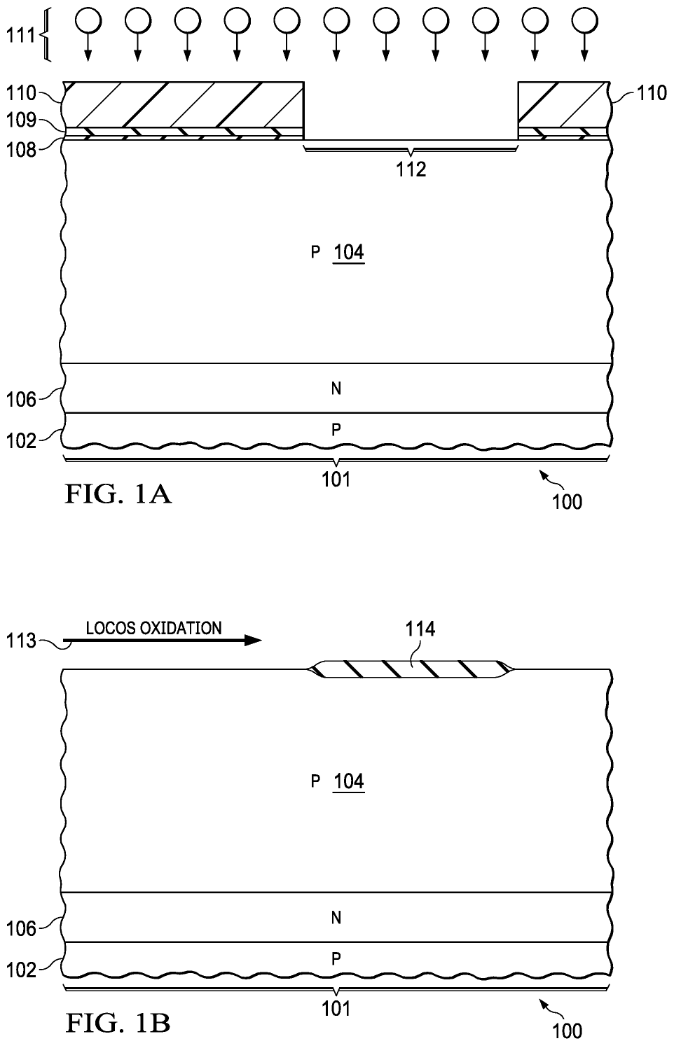

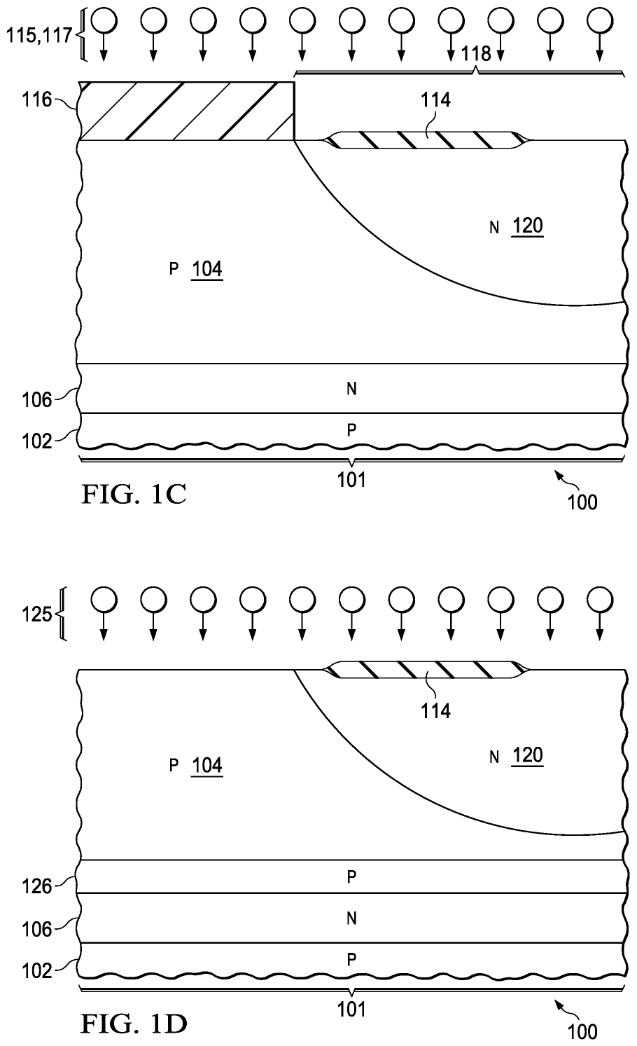

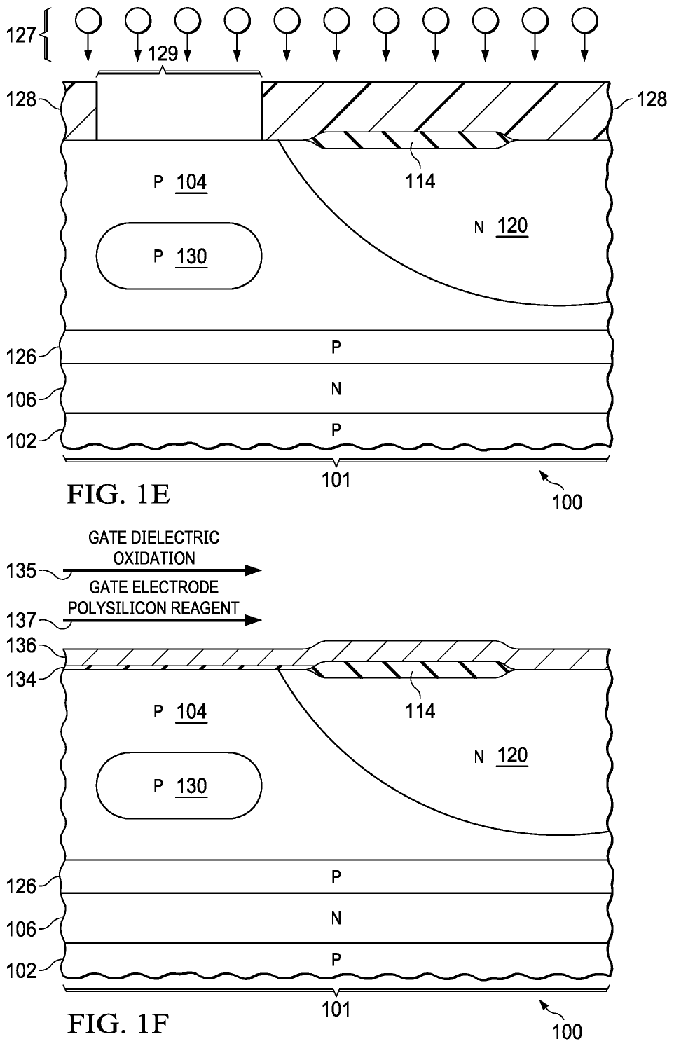

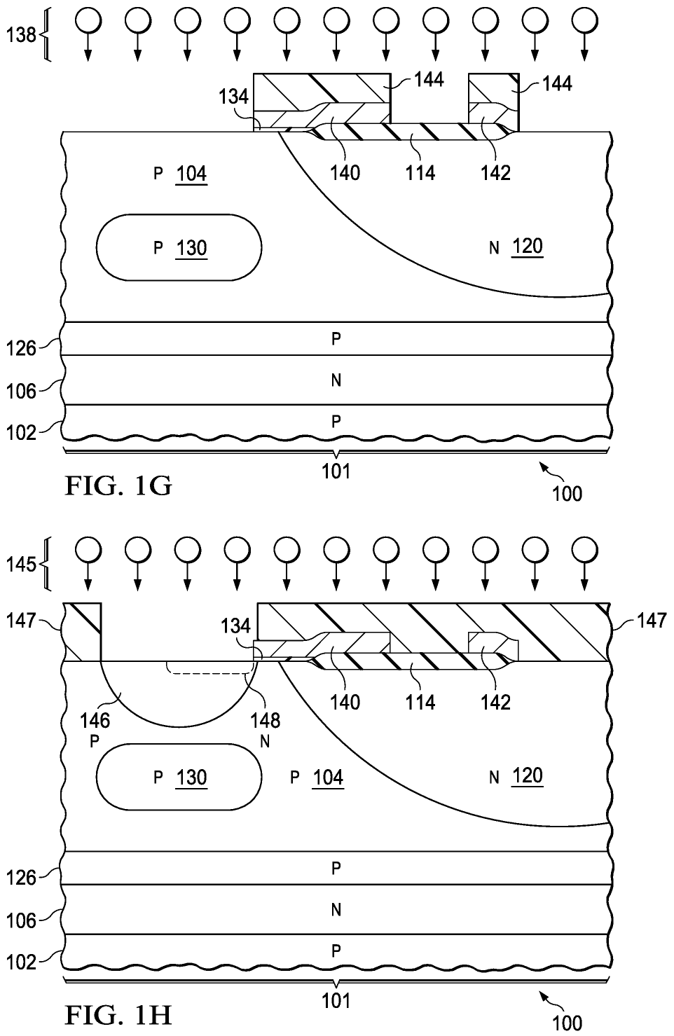

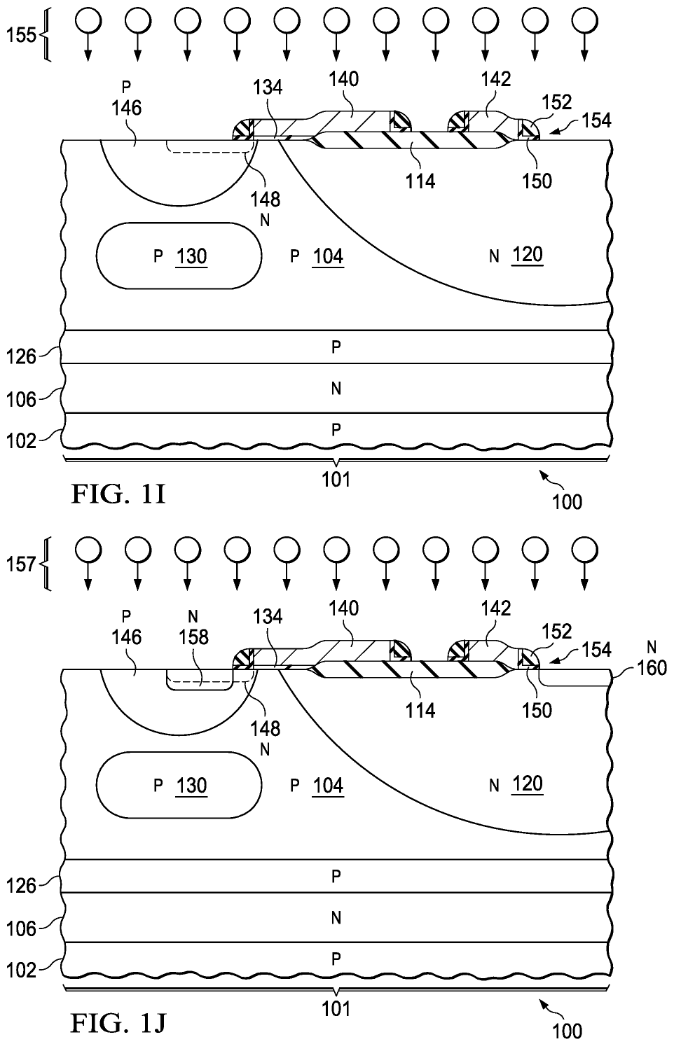

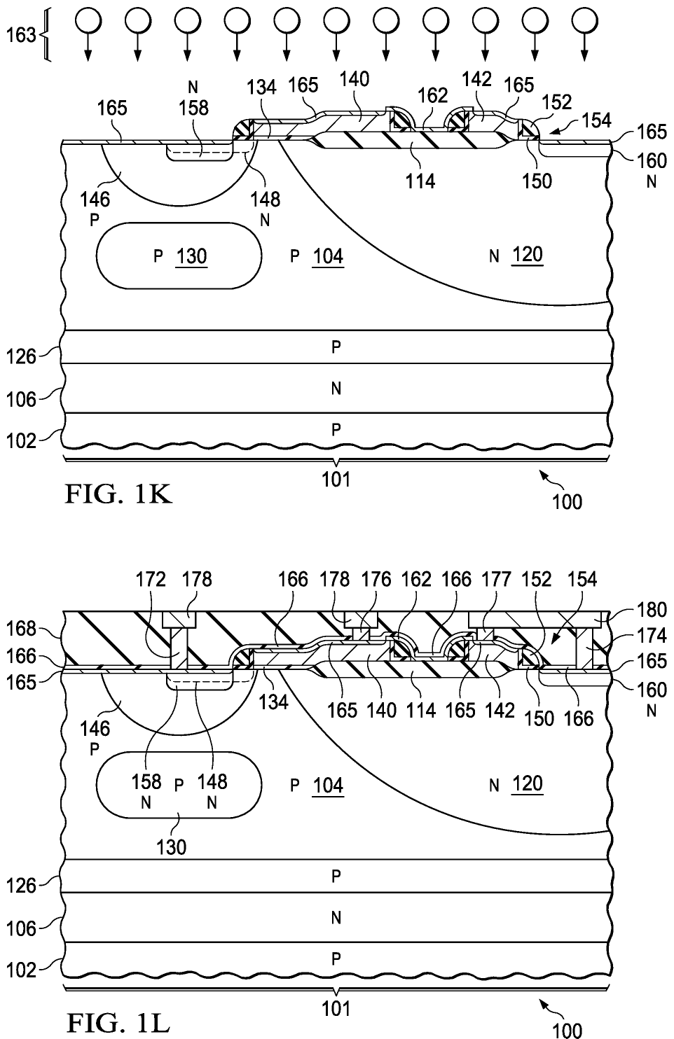

Shown in FIG. 1A through FIG. 1L is a method of forming a semiconductor device 100 under a sequence that forms a laterally diffused metal oxide semiconductor (LDMOS) transistor 101. Although NMOS LDMOS transistors 101 are described herein, it is clear that p-channel metal oxide transistors (PMOS) LDMOS transistors 101, can be formed when n-doped regions or regions of the first conductivity type are substituted by p-doped regions. Likewise, p-doped regions or regions of the second conductivity type are substituted by n-doped regions.

FIG. 1A shows a semiconductor device 100 at the point in the process flow where a lightly doped p-type epitaxial layer has been grown on a p-type substrate 102, and a portion of the epitaxial layer has been processed, e.g. by dopant implantation, to form an n-type buried layer (NBL) 106 under an EPI layer 104. As will become apparent in the discussion the EPI layer 104 may serve as a body region of the LDMOS transistor 101, and sometimes may be referred to for convenience or clarity as body region 104. While the NBL 106 is shown in FIG. 1A, an NBL can be optional for building a LDMOS device. The p-type substrate 102 and the EPI layer 104 can both include silicon, and can also comprise other materials. A pad oxide layer 108 of silicon dioxide may be formed on the EPI 104. The pad oxide layer 108 may include silicon dioxide that is formed by a thermal oxidation process or a chemical vapor deposition (CVD) process. The pad oxide layer 108 provides stress relief between the EPI 104 and subsequent layers. The pad oxide layer 108 may be 5 nm to 50 nm thick, by way of example. A silicon nitride layer 109 is then deposited and a photomask 110 is formed. The photomask 110 serves the function of masking the silicon nitride layer 109 and it may include a light sensitive organic material that is coated, exposed and developed. The photomask 110 step is followed by a plasma etch process 111 which removes the silicon nitride layer 109 and exposes the EPI 104 in a region 112 that will eventually form a field relief dielectric layer 114, shown in FIG. 1B, which includes a local oxidation of silicon (LOCOS) layer of silicon dioxide with tapered ends.

Referring to FIG. 1B, the semiconductor device 100 is shown after a furnace oxidation 113 to form the field relief dielectric layer 114 and after a subsequent wet chemical removal (not shown) of the silicon nitride layer 109. In various examples the LOCOS field relief dielectric layer 114 has a thickness in a range between 50 nm and 150 nm. Dielectric layers such as the field relief dielectric layer 114 derived from LOCOS type processing have become thinner near their perimeter and end in a “birds beak” where the field relief dielectric layer 114 meets the EPI 104.

Referring to FIG. 1C, a photomask 116 is deposited and patterned with an opening in region 118 where a drift region (NDRIFT) implant is to be implanted to form an NDRIFT drain drift region 120 within the exposed areas of the EPI 104. The implant to define the NDRIFT region occurs in two steps. In one example, the initial implantation process implants phosphorous dopants at the first energy of 20-40 kilo-electron volts (keV) and the first dose of 2-8×10¹² cm⁻². In one implementation, the first implantation process 115 implants phosphorus dopants in a region 118 at the first energy of 20-40 keV for an oxide thickness of 70-110 nm. In another example, the first dose is 2-5×10¹² cm⁻². The second implant process uses the same photomask 116 to implant the same region 118. In one example, the second energy is greater than the first. In one example, the second implantation process 117 implants phosphorus dopants at the second energy of 70-350 keV and the second dose of 2-5×10¹² cm⁻². In one example, the second implantation process 117 implants phosphorus dopants at the second energy less than or equal to 150 keV. In one example, the second implantation process 117 implants phosphorus dopants at the second energy greater than or equal to 100 keV, such as 100-350 keV. In one example, the second implantation process 117 includes more than one implant, for example, an implantation at 120 keV, and another implantation at 250 keV.

Referring to FIG. 1D, a p-type buried layer (PBL) 126 is formed using a high energy p-type implant (PBL implant) 125 to add doping to the p-epi layer 104. The PBL implant 125 can comprise boron at a dose from 1×10¹² cm⁻² to 1×10¹³ cm⁻² at an energy of 400 keV to 3 mega-electron volts (MeV). Indium may also be used as the implant species. For low voltage (e.g., 20 V) versions of the LDMOS transistor 101, the PBL implant 125 can be a blanket implant, while for higher voltage (e.g., >30 V) versions of the LDMOS transistor 101, the PBL implant 125 can be a masked implant to allow selective placement. For the masked implant, a photomask (not specifically shown) is deposited and patterned with an opening which exposes regions of the EPI 104 where the PBL implant 125 is to be implanted. The PBL implant 125 is followed by a thermal drive (not specifically shown) which extends the PBL implant 125 below the drift region. The dedicated thermal drive is optional as the activation of the PBL implant 125 can also be done during the same damage anneal as used after SNWELL (shallow N-well) and SPWELL (shallow P-well) implants.

Referring to FIG. 1E, a photomask 128 is deposited and patterned with an opening 129 which exposes regions for a SPWELL 130 in EPI 104 under a p-type deep well (DWELL) region 146, shown in FIG. 1H. An SPWELL ion implantation 127 implants p-type dopants within the exposed areas of the EPI 104 to form the SPWELL 130. The SPWELL ion implantation 127 can comprise two or more SPWELL implants, all at different energies. Body region doping provided by SPWELL 130 increases a base doping level to suppress a parasitic lateral NPN bipolar formed by N+ source-p-body-N+ drain. This parasitic NPN limits high current operation for the LDMOS transistor 101 as it forms a boundary to the safe operating area (SOA).

Referring to FIG. 1F, a gate dielectric layer 134 is first formed in a high temperature furnace operation or a rapid thermal process 135. The gate dielectric layer 134 thickness can range from approximately 3 nm to 15 nm for silicon dioxide or a silicon oxynitride (SiON) gate dielectric that is slightly thinner but with a higher dielectric constant than that of silicon dioxide, which is about 3.9, by way of example. After the gate dielectric layer 134 is formed, a gate electrode layer 136 is deposited by a gate deposition process 137 on the wafer using any of a number of silane based precursors. Polycrystalline silicon is one example of a material for the gate electrode layer 136, however a metal gate or CMOS-based replacement gate electrode process can also be used to provide the gate electrode layer 136. The gate electrode layer 136 in this example is polycrystalline silicon. The layer of polycrystalline silicon of the gate electrode layer 136 is also used for a drain-tied field plate 142 shown in FIG. 1G.

Referring to FIG. 1G, after the gate dielectric layer 134 and gate electrode layer 136 of FIG. 1F are deposited, a photomask 144 is deposited and patterned. A plasma etch process 138 is used to define the gate electrode 140 and the drain-tied field plate 142. After the plasma etch process is complete, photomask 144 is removed and a wet or dry process is used to clean the wafer surface. A space between the gate electrode 140 and drain-tied field plate 142 of between 200 nm and 600 nm is used to preclude merging of sidewall spacers during later processing and a poly silicon critical dimension of between 100 nm and 300 nm for the field plate 142 is used to allow formation of low sheet resistance silicide. The gate dielectric layer 134 extends over a channel region of the LDMOS transistor 101. The channel region extends partway over the NDRIFT drift region 120, and partway over the EPI 104. In the illustrated example the field plate 142 extends over the tapered end of the field relief dielectric layer 114 towards the drain.

Conventionally, an LDMOS device may be configured such that an edge of a depletion region between a body region and a drift region may reach a drain region during reverse bias. This event may lead to snap-back, which may be detrimental to device performance. In contrast, examples of the present disclosure provide the addition of the field plate 142 located over the edge of the field relief dielectric layer 114, e.g. over the bird's beak. Such placement is expected to result in the termination of electric field lines, thereby reducing the drain-to-source breakdown voltage (BVDSS) relative to what it would be without the field plate 142, in which case a snap-back breakdown would be expected to occur under reverse bias when the depletion edge reaches the drain region 160 (described below with respect to FIG. 1J). Instead, the field plate 142 is expected to result in a low current avalanche breakdown before the depletion edge reaches the field plate 141, at the expense of reduced breakdown voltage. This tradeoff is contrary to conventional practice, which prioritizes greater breakdown voltage. While the low current BVDSS failure mechanism reduces breakdown voltage, the high current NPN breakdown mechanism is unaffected. The overall result is increased SOA and increased ruggedness of the LDMOS device. An additional benefit is lower on-resistance (Rsp) as the addition of the field plate at the field relief layer edge allows the drain implant to be self-aligned to the edge of the field plate. This reduces the half pitch of the device and thus lowers Rsp.

Referring to FIG. 1H, after the wafer is cleaned, an implant mask 147 is formed over the semiconductor device 100 to expose an area over the SPWELL 130. A DWELL implant process 145 implants p-type dopants into a portion of the EPI 104 laterally adjacent to the NDRIFT region including at least a first well ion implant comprising a p-type dopant to form the p-type DWELL region 146. The p-type dopants implanted by the DWELL implant process 145 may include boron. Besides boron, the p-type dopants can include indium (In). Indium, being a relatively large atom, has the advantage of a low diffusion coefficient relative to boron. In the case of a boron implant, the DWELL boron implant can be similar in energy to energies used to form p-type source/drain regions or p-type lightly doped drain regions in a semiconductor device process, and the dose used should generally be sufficient to enable formation of a channel laterally and to be suppress body NPN effects during operation of the LDMOS transistor 101. For example, a boron implant with an energy of 20 keV, a dose of 8×10¹³ cm⁻² to 3.0×10¹⁴ cm⁻², such a 1.5×10¹⁴ cm², and a tilt angle of less than 5 degrees, such as 2 degrees may be used. Optionally, an n-type dopant such as arsenic or antimony can also be added to a source side of the LDMOS transistor 101 (resist pattern not shown) to form an n-type DWELL region 148. For example, arsenic with a dose 5×10¹³ cm⁻² to 1.2×10¹⁵ cm⁻² (e.g., 8×10¹⁴ cm⁻²) an energy 10 keV to 50 keV (e.g., 15 keV and a 15 degree ion implant tilt angle) may be used in one particular example for the n-type DWELL region 148 dopant, or some or all of this implant angled for example 45 degrees (2 or 4 rotations). The implant angle can also be straight as well (at 0 degrees) or from zero to 45 degrees. An arsenic energy of about 15 keV can allow the arsenic to penetrate through the gate dielectric layer 134 (e.g., when a 5V oxide is used for gate dielectric) adjacent to the gate electrode 140 which reduces the net doping concentration there by counter doping so as to reduce gate-induced parametric shifts. The 15 degree or so arsenic implant angle can reduce the channel voltage threshold (Vt) without reducing the p-type DWELL region 146 implant dose, enabling the simultaneous improvement of Vt and control of the body doping of the parasitic NPN. The p-type DWELL region 146 arsenic can range between 5-50 keV with the angle from 0 degrees to 45 degrees. Additionally, the arsenic dose may be made in more than one step to put most of the arsenic dose in the vertical implant and the rest into the angled implant. After the DWELL implant process 145, a polysilicon oxidation step is carried out to minimize gate-to-drain capacitance (CGD) and gate-to-source capacitance (CGS). The polysilicon oxidation also provides the thermal budget for the DWELL boron dopant to diffuse past the DWELL arsenic, forming the channel profile in the lateral direction and putting some P+ type silicon under the source to suppress lateral NPN breakdown effects during high power operation. After the polysilicon oxidation, lightly doped drain (LDD) implants are patterned, implanted (not specifically shown) followed by activation of the dopants by a rapid thermal process (RTP).

Referring to FIG. 1I, after the p-type DWELL region 146 and the n-type DWELL region 148 are formed, an oxide layer 150 and a nitride layer 152 are deposited over the entire wafer surface. After the deposition of the oxide layer 150 and nitride layer 152, a blanket anisotropic plasma etch process 155 is used to remove portions of the oxide layer 150 and portions of the nitride layer 152, to form a sidewall spacer 154 of dielectric material on the gate electrode 140 and on the drain-tied field plate 142. The sidewall spacer 154 overlaps an edge of the field relief dielectric layer 114 adjacent to a drain region. In one example, the nitride layer 152 may be deposited across the surface of the wafer and etched to form a nitride-only sidewall spacer 154.

Referring to FIG. 1J, a patterning step (not specifically shown) and an ion implantation step 157 are used to implant a source region 158 in the p-type DWELL region 146, and to implant a drain region 160 in the NDRIFT drain drift region 120. The ion implantation step 157 uses an edge of the sidewall spacer 154 to self-align the drain region 160 to the drain-tied field plate 142. The drain region 160 contains an average dopant density at least twice that of the NDRIFT drain drift region 120. The drain-tied field plate 142 extends between the drain region 160 and the gate electrode 140 over a distance that is greater than twice the thickness of the field relief dielectric layer 114. Also, in the illustrated example the drain-tied field plate 142 overlaps the bird's beak of the drain-side of the field relief dielectric layer 114, and is spaced apart from the drain region 160 by the sidewall spacer 154.

Referring to FIG. 1K, a silicide blocking layer 162 is formed by depositing a one or more sublayers of an oxide, a nitride, an oxynitride, or any combination thereof over the entire wafer. The silicide blocking layer 162 is patterned (not specifically shown) and one or more sublayers are etched away 163 in regions of EPI 104, the gate electrode 140, and the drain-tied field plate 142 where a metal silicide layer 165 is to be formed. The silicide blocking layer 162 is allowed to remain in areas on the EPI 104, the gate electrode 140, and the drain-tied field plate 142 at the wafer surface where silicide is not intended to be formed. In at least one implementation, the silicide blocking layer 162 is not required for LDMOS formation, and may be omitted. After the silicide blocking layer 162 has been formed, a metal layer (not specifically shown) which forms a metal silicide at temperatures consistent with silicon processing conditions is deposited on the wafer surface. The semiconductor device 100 is heated to form the metal silicide layer 165 in exposed regions of the EPI 104, the gate electrode 140, and the drain-tied field plate 142. Unreacted metal is subsequently removed in a wet stripping process which is not specifically shown.

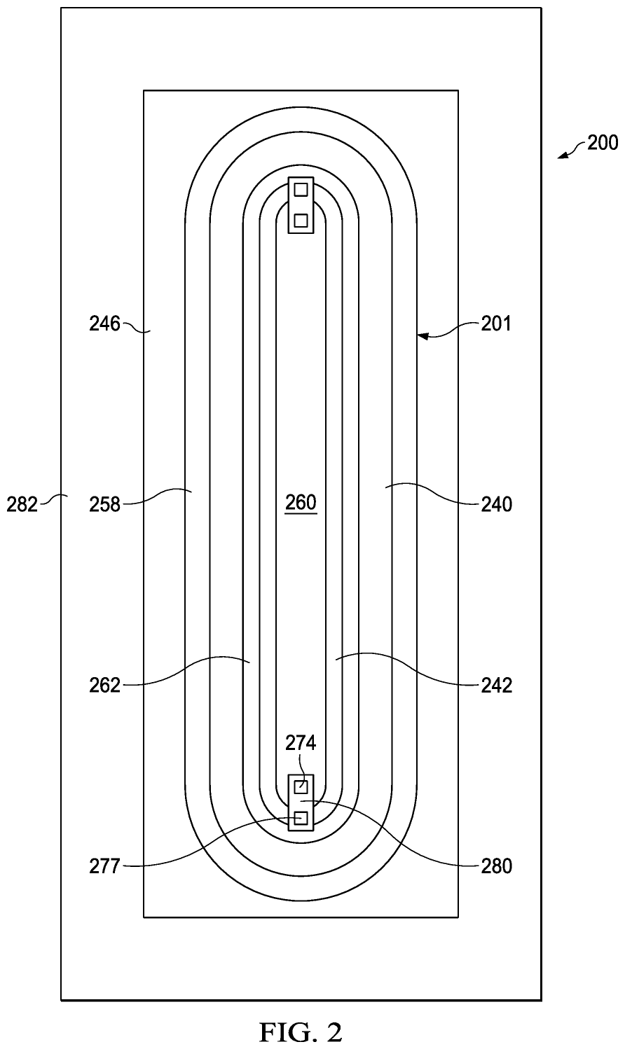

Referring to FIG. 1L, a cross section of the completed semiconductor device 100 through the first level of metal interconnect system is shown. After the metal silicide layer 165 formed, a nitride etch stop layer 166 is deposited, followed by deposition of a pre-metal dielectric 168 (PMD). A source/IBG contact 172, a drain contact 174, a gate contact 176, and a field plate contact 177 are patterned, etched, and filled with a suitable metal such as tungsten. The backgate/body region (not specifically shown) is out of the plane of the FIGS. 1L and 1s ohmically shorted to the n-source region 158 through the metal silicide layer 165. The backgate/body region (within the region defined by source 158 in FIG. 2) can be formed within the p-type DWELL region 146 by adding a p-type source/drain (PSD) implant used for the CMOS section of the process flow, which is very heavily (P+ boron) doped.

The metal interconnects 178 (aluminum or copper) and back end processing (not specifically shown) complete the semiconductor device 100. The electrical connection between a first contact to the LDMOS field plate contact 177 and a second contact to the LDMOS drain contact 174 is made through metal one 180, but could also be made through other metal layers. FIG. 2 is a top view of an example semiconductor device 200 that includes an LDMOS transistor 201 with a drain-tied field plate 242 to enhance LDMOS ruggedness, where a source 258, gate electrode 240 and the drain-tied field plate 242 are in a “racetrack” or closed-loop configuration according to an example implementation. The drain-tied field plate 242 can be formed with rounded corners to reduce electric fields. In this context, the term “corner” refers to the transition of the direction of the drain-tied field plate 242 from one direction to another direction, e.g. a transition from a first direction to an orthogonal second direction. In one example the drain-tied field plate 242 has rounded corners with radii greater than a thickness of the drain-tied field plate 242. A silicide blocking layer 262 is between the gate electrode 240 and the drain-tied field plate 242. Contact 277 is connected from the drain-tied field plate 242 to drain contact 274 and drain 260 through a metal one interconnect 280 by way of example. An isolation tank 282 along with DWELL 246 is shown framing the LDMOS transistor 201 which as described above can comprise an NBL 206 together with an N+ sinker providing vertical walls compiling a top surface of an EPI layer 204 to the NBL 206.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present invention should not be limited by any of the above described examples. Rather, the scope of the disclosure should be defined in accordance with the following claims and their equivalents.

What is claimed:

1. A semiconductor device, comprising:
an epitaxial layer over a semiconductor substrate, the epitaxial layer including a body region having a first conductivity type and a drain drift region having a second, opposite, conductivity type;
a gate dielectric layer over the body region and extending over a junction between the body region and the drain drift region;
a gate electrode over the gate dielectric layer;
a drain region having the second conductivity type in the drain drift region, the drain region having an average dopant density greater than an average dopant density of the drain drift region;
a field relief dielectric layer over the drain drift region, the field relief dielectric layer extending from the gate dielectric layer toward the drain region and having a thickness greater than the gate dielectric layer; and
a field plate located over the field relief dielectric layer and between the gate electrode and the drain region, the field plate conductively connected to the drain region.

2. The semiconductor device of claim 1, wherein the drain-tied field plate follows a path that has rounded corners with radii greater than a thickness of the field plate.

3. The semiconductor device of claim 1, wherein the field plate runs about parallel to the drain region.

4. The semiconductor device of claim 1, wherein the field relief dielectric layer includes a local oxidation of silicon (LOCOS) layer of silicon dioxide with a tapered edge, and the field plate is located over the tapered edge.

5. The semiconductor device of claim 1, wherein:
the gate electrode extends over the field relief dielectric layer and is spaced apart from the field plate by a silicide blocking layer.

6. The semiconductor device of claim 1, wherein the first conductivity type is p-type and the second conductivity type is n-type.

7. The semiconductor device of claim 1, wherein the field plate includes polycrystalline silicon.

8. The semiconductor device of claim 1, wherein the gate electrode and the field plate have a closed-loop configuration.

9. The semiconductor device of claim 1, wherein the field plate extends between the drain region and the gate by a distance that is at least twice the thickness of the field relief dielectric layer.

10. The semiconductor device of claim 1, wherein the field plate extends over a tapered edge of the field relief dielectric layer.

11. A method of forming a semiconductor device, comprising:
forming a body region and a drift region in a semiconductor layer, the body region having a first conductivity type and the drift region having a second, opposite, conductivity type;
forming a gate dielectric layer over the body region, the gate dielectric layer extending over a junction between the body region and the drift region;
forming a field relief dielectric layer over the drift region, the field relief dielectric layer having a greater thickness than the gate dielectric layer;
forming a gate electrode over the gate dielectric layer and a field plate over the field relief dielectric layer, the field plate being spaced apart from the gate electrode;
forming a drain region having the second conductivity type in the drain drift region, the drain region having an average dopant density greater than an average dopant density of the drain drift region; and
forming a conductive connection between the field plate and the drain region.

12. The method of claim 11, wherein the field plate is formed concurrently with the gate electrode.

13. The method of claim 11, wherein the drain region is formed by implanting dopants of the second conductivity type into the drift region using the field plate to block the dopants of the second conductivity type at a perimeter of the drain region.

14. The method of claim 11, wherein the field plate is located over an edge of the field relief dielectric layer.

15. The method of claim 11, further comprising:
forming a silicide blocking layer on the field relief dielectric layer between the gate electrode and the field plate; and
forming a metal silicide over the drain region.

16. The method of claim 11, wherein the field relief dielectric layer is formed by a local oxidation of silicon (LOCOS) process.

17. The method of claim 11, wherein the first conductivity type is p-type and the second conductivity type is n-type.

18. The method of claim 11, further comprising forming a sidewall spacer of dielectric material abutting the field plate and between the field plate and the drain region.
